(19) United States
(12) Patent Application Publication
(10) Pub. No.: US 2007/0045843 A1
(43) Pub. Date: Mar. 1, 2007

(54) Substrate for a ball grid array and a method for fabricating the same

(75) Inventors: Rudiger Uhlmann, Dresden (DE); Maik Ruemmler, Dresden (DE)

Correspondence Address: MORRISON & FOERSTER LLP, 1650 TYSONS BOULEVARD, SUITE 300, MCLEAN, VA, 22102, US

(73) Assignee: INFINEON TECHNOLOGIES AG, Munich (DE)

(21) Appl. No.: 11/211,080

(22) Filed: Aug. 25, 2005

(51) Int. Cl. H01L 23/48

(52) U.S. Cl. 257/738

(57) ABSTRACT

The present invention relates to a substrate for a Ball Grid Array device comprising a support element, a solder ball pad arranged on the support element and adapted to be applied by a solder bump, a bond pad arranged on the support element and adapted to be bonded by a bond wire and a silver layer provided on both the solder pad and the bond pad.

### TECHNICAL FIELD OF THE INVENTION

The present invention is related to a substrate for a ball grid array, especially a substrate having both a solder ball pad and a bond pad. The present invention is further related to a method for fabricating such a substrate.

### BACKGROUND OF THE INVENTION

A common ball grid array device (BGA) comprises a substrate having a rewiring structure a number of bond pads for bond wires as well as a number of solder ball pads for applying solder balls. By means of the solder balls, the BGA-device can be contacted externally. The bond pads are used to provide contacting between the substrate and an integrated circuit chip to be applied thereon so that the integrated circuit chip can be signalled via the solder balls of the substrate.

Usually, the pads comprise a conducting material such as copper, and the like. Both kinds of contact pads are coated with a layer of nickel and a layer of gold.

The mechanical fixing of the connection between the solder ball and the solder ball pad is sufficient when using solder balls including an alloy of tin, lead and silver.

Most recently, attempts are being made to ban lead-containing materials in the manufacturing of electronic devices. One measure is to use solder of an alloy containing the materials tin, silver and copper. This new solder material has the disadvantage that the mechanical stability of a solder ball on a nickel layer is unreliable due to the bad adhesion strength between the nickel layer and the new solder material because of the lack of lead.

To overcome this issue the solder ball pads can be made of materials that do not contain nickel. However, this requires different process steps for the manufacturing of the bond pads and the solder ball pads.

### SUMMARY OF THE INVENTION

The present invention includes a bond pad for bonding a bond wire to provide a substrate using common bonding technology and a solder ball pad for attaching a lead-free solder ball and wherein the number of process steps for manufacturing the solder ball pads and the bond pad is minimized, and to a method for fabricating such a substrate.

According to a first aspect of the present invention, a substrate for a ball grid array device is provided which comprises a support element, a solder ball pad arranged on the support element and adapted to be applied by a solder bump, a bond pad arranged on the support element and adapted to be bonded by a bond wire and a silver layer provided on both the solder pad and the bond pad.

The silver layer which is applied on the solder pad as well as on the bond pad allow for further processing of the substrate by depositing a solder ball on the solder ball pad and the bondwire on the bond pad. The solder ball pad coated with a silver layer allows for applying a solder ball with a solder material not containing lead and providing a sufficient mechanical stability which is required by a ball grid array device with such a substrate. Furthermore, the silver coated bond pads can be bonded by using a common bonding technology.

Preferably, both the solder ball pad and the bond pad are located on the same surface of the support element.

According to another embodiment of the present invention, at least one of the solder ball pads and the bond pad comprise a copper structure. Preferably the thickness of the silver layer ranges from 2 to 10 μm.

According to another aspect of the present invention, a substrate for a ball grid array device is provided comprising a support element, a solder ball pad arranged on the support element, a solder bump which is arranged on the solder ball pad, a bond pad arranged on the support element and adapted to be bonded by a bond wire, wherein at least the bond pad is provided with a silver layer.

According to another aspect of the present invention, a method for fabricating a substrate for a ball grid array device is provided. The method comprises the steps of providing a support element, arranging a solder ball on the support element which is adapted to be applied by a solder bump, arranging a bond pad on the support element which is adapted to be bonded by a bond wire, providing a silver layer on both the solder ball pad and the bond pad.

The method of the present invention provides a way to fabricate a substrate having a solder ball pad and a bond pad wherein the fabricating of the solder ball pad and the bond pad uses a common process step such as providing the silver layer as a top layer of the pads.

Preferably both the solder ball pad and the bond pad are located on the same surface of the support element.

According to a preferred embodiment of the present invention at least one of the solder ball pad and the bond pad are provided with a copper structure.

Preferably the thickness of the silver layer is selected to be within the range from 2 to 10 μm.

According to a preferred embodiment of the present invention a solder element which is applied on the solder ball pad comprises an alloy containing the materials tin, silver and copper. Preferably the solder element does not contain the material lead.

### BRIEF DESCRIPTION OF THE DRAWINGS

The invention is described below in more detail with reference to exemplary embodiments and the drawings, in which:

FIG. 1 is a cross-sectional view of a substrate for a ball grid array.

FIG. 2 is a top view of a substrate for a ball grid array on which solder elements are applied.

### DETAILED DESCRIPTION OF THE INVENTION

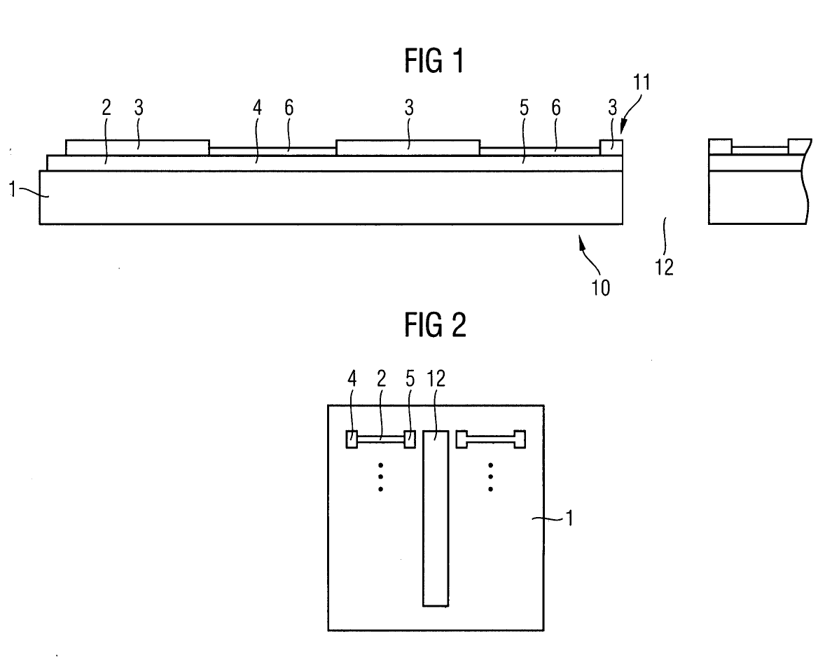

In FIG. 1, a substrate 1 for a ball grid array is shown which has a first surface 10 and a second surface 11. The first surface 10 is adapted in such a way that one or more chips can be arranged thereon so that the ball grid array device can be formed. The substrate 1 further comprises a through-channel 12 through which bond wires (not shown) can be led for connecting chips to be applied on the first surface 10 and bond pads which are described below.

On the second surface 11 a re-wiring layer including a connecting structure 2 is provided. The connecting structure 2 is usually made of copper although other materials can be provided for producing the conducting structure.

As shown in the top view of FIG. 2 the substrate 1 has the conducting structure 2 which forms a solder ball pad 4 for applying a solder ball and a bond pad for a bond wire led through the through-channel 12 of the substrate 1. The size of the solder ball pad 4 is such that a solder ball (not shown) can easily be applied thereon. At least on the solder ball pad 4 and the bond pad 5 of the conducting structure 2, the silver layer 6 can be deposited. The silver layer 6 allows for a solder ball to be easily soldered to the solder ball pad 4, even if the material of the solder ball does not contain lead. New materials for solder balls are lead-free and comprise an alloy of tin, silver and copper which can easily be soldered on the solder ball structure comprising the layer of copper and the layer of silver thereon.

On the other hand, the bond pad 5 is also made of the connecting structure 2 on which a silver layer 6 is provided which can easily be bonded by conventional bonding technologies, using bond wires made of aluminum, copper, gold, or alloys thereof. Moreover, metallic coating may improve the bonding properties and the contacting properties of the surface of the bond wire. The connecting structure 2 and the silver layer 6 applied thereon can be structured with conventional lithography technology which is commonly known in the art.

Prior to applying the solder ball on the solder ball pad 4, a solder ball pad 4 is surrounded by a solder stop layer 3 which is also structured by a common lithography technology.

According to another embodiment of the present invention the bond pads can also be applied on the first surface 10 of the substrate 1 wherein a rewiring structure is provided within the substrate 1 to connect the solder ball pad 4 with the bond pad 5.

The silver layer 6 is preferably coated by means of a galvanic deposition, current-free chemical deposition or other depositing processes and provided with a thickness of 2 to 10 μm.

What is claimed is:

1. A substrate for a Ball Grid Array device, comprising:
a support element;
a solder ball pad arranged on the support element and adapted to be applied by a solder bump;
a bond pad arranged on the support element and adapted to be bonded by a bond wire; and
a silver layer provided on both the solder pad and the bond pad.

2. The substrate according to claim 1, wherein both the solder ball pad and the bond pad are located on a same surface of the support element.

3. The substrate according to claim 1, wherein at least one of the solder ball pad and the bond pad comprises a copper structure.

4. The substrate according to claim 1, wherein the thickness of the silver layer ranges from 2-10 μm.

5. A substrate for a Ball Grid Array device, comprising:
a support element;
a solder ball pad on the support element;
a solder element applied on the solder ball pad; and
a bond pad arranged on the support element and adapted to be bonded by a bond wire,
wherein at least the bond pad is provided with a silver layer.

6. A method for fabricating a substrate for a Ball Grid Array device, comprising:
providing a support element;
arranging a solder ball pad on the support element which is adapted to be applied by a solder bump;
arranging a bond pad on the support element which is adapted to be bonded by a bond wire; and
providing a silver layer on both the solder ball pad and the bond pad.

7. The method according to claim 6, wherein both the solder ball pad and the bond pad are located on a same surface of the support element.

8. The method according to claim 6, wherein at least one of the solder ball pad and the bond pad is provided with a copper structure.

9. The method according to claim 6, wherein the thickness of the silver layer is selected in a range from 2-10 μm.
